(19) United States
(12) Patent Application Publication
(10) Pub. No.: US 2008/0174020 A1
(43) Pub. Date: Jul. 24, 2008

(54) Electronic device having metal pad structure and method of fabricating the same

(75) Inventor: Jae-Whoan Ga, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/000,053

(22) Filed: Dec. 7, 2007

(30) Foreign Application Priority Data
Jan. 23, 2007 (KR) 10-2007-0006947

(51) Int. Cl. H01L 23/52; H01L 21/44

(52) U.S. Cl. 257/751; 438/612; 257/E23.141; 257/E21.476

(57) ABSTRACT

An electronic device may include a protective insulating layer formed over a substrate. A plurality of metal pad structures may be spaced apart from one another. Each of the plurality of metal pad structures may pass through the protective insulating layer and/or have a top surface disposed at a higher level than the protective insulating layer. Insulating barrier spacers may be on sidewalls of the metal pad structures. Each of the insulating barrier spacers may include a top surface disposed at a higher level than the metal pad structures.

### PRIORITY STATEMENT

This application claims the benefit of priority to Korean Patent Application No. 10-2007-0006947, filed on Jan. 23, 2007, in the Korean Intellectual Property Office, the entire contents of which are incorporated herein in their entirety by reference.

### BACKGROUND

1. Field

Example embodiments relate to an electronic device and/or a method of fabricating the same, and for example, to an electronic device having a metal pad structure and/or a method of fabricating the same.

2. Description of Related Art

Examples of recent core technology that make rapid development of electronic devices possible are semiconductor device fabrication technology and semiconductor packaging technology. Fabrication technology for semiconductor devices is developing toward finer line widths, multi-layered interconnections, etc. For example, as semiconductor devices are more highly integrated, a technology of employing multi-layered metal interconnections is more widely used. The multi-layered metal interconnections are formed of a copper interconnection having a damascene interconnect structure with lower resistivity and higher reliability in order to improve performance of the semiconductor device. Semiconductor packaging technology is developing from initial plated-through packages, for example, a pin grid array (PGA), toward finer-pitch surface mounted packages that are smaller and have better electric performance. Semiconductor packing technology is developing toward multichip modules (MCM), system in packages (SIP), or system on packages (SOP). The aforementioned semiconductor packages require smaller size, higher density, lower power consumption, multi-function, ultra high-speed signal processing, and higher reliability. A semiconductor device may be packaged by a semiconductor packaging process. For example, the semiconductor device is bonded to a package base, and the semiconductor device and the package base are electrically connected by a bonding wire. For example, the semiconductor device may be a semiconductor chip. The package base may be a package substrate, for example, a lead frame.

A conventional semiconductor device may have a conventional bonding pad structure employing copper interconnections. The copper interconnections are formed, and bonding pad structures formed of an aluminum layer are formed on a substrate having the copper interconnections. Sidewalls of the bonding pad structures are exposed. The bonding pad structures are bonded by bonding wires in a packaging process.

As semiconductor devices are scaled down, pitches of the bonding pad structures are reduced. The reduction in pitch of the bonding pad structures includes a reduction in size of the bonding pad structures and a reduction in distance between the bonding pad structures, which results in a reduction in distance between the bonding wires in contact with the bonding pad structures. The bonding wires may have a larger width at a portion contacting the bonding pad structures. Accordingly, in a conventional electronic device employing conventional bonding pad structures, an electrical short circuit may occur between the bonding wires at the portion of the bonding wires contacting the bonding pad structures.

### SUMMARY

An example embodiment may provide an electronic device having a metal pad structure which may reduce an occurrence of an electrical short circuit between bonding wires.

Another example embodiment may provide a method of fabricating an electronic device having a metal pad structure which may reduce an occurrence of an electrical short circuit between bonding wires.

According to an example embodiment, an electronic device may include a substrate, a protective insulating layer, a plurality of metal pad structures, and/or insulating barrier spacers. The protective insulating layer may be formed over the substrate. The plurality of metal pad structures may be spaced apart from one another. Each of the plurality of metal pad structures may pass through the protective insulating layer and/or including a top surface disposed at a higher level than the protective insulating layer. The insulating barrier spacers may be on sidewalls of the plurality of metal pad structures. Each of the insulating barrier spacers may include a top surface disposed at a higher level than the metal pad structures.

According to an example embodiment, the plurality of metal pad structures may have a first width at a first part passing through the protective insulating layer and a second width larger than the first width at a second part disposed at a higher level than the protective insulating layer.

According to an example embodiment, the plurality of metal pad structures may partially cover a top surface of the protective insulating layer.

According to an example embodiment, the plurality of metal pad structures may be at least one of an aluninum (Al) layer and an aluminum (Al) alloy layer.

According to an example embodiment, the insulating barrier spacers may be disposed at a higher level than the protective insulating layer.

According to an example embodiment, the insulating barrier spacers may cover sidewalls of the metal pad structures and/or a top surface of the protective insulating layer between the metal pad structures.

According to an example embodiment, the insulating barrier spacers may include a silicon nitride layer.

According to an example embodiment, the electronic device may include an insulating buffer pattern formed outside the insulating barrier spacers and filling a space between each of the plurality of metal pad structures.

According to an example embodiment, the electronic device may include an interlayer insulating layer formed between the substrate and the protective insulating layer, and/or metal patterns passing through the interlayer insulating layer and electrically connected to the plurality of metal pad structures.

According to an example embodiment, the metal patterns may include copper (Cu) interconnections.

According to an example embodiment, the electronic device may include barrier patterns interposed between the metal patterns and the metal pad structures.

According to an example embodiment, the electronic device may include bonding wires on the plurality of metal pad structures.

According to an example embodiment, a portion of each of the bonding wires contacting the plurality of metal pad structures may be wider than another portion of each of the bonding wires.

According to an example embodiment, a method of fabricating an electronic device may include forming a plurality of metal pad structures spaced apart from one another and passing through a protective insulating layer formed over a substrate, each of the plurality of metal pad structures including a top surface disposed at a higher level than the protective insulating layer. Insulating barrier spacers may be formed on sidewalls of the plurality of metal pad structures, each of the insulating barrier spacers including a top surface disposed at a higher level than the metal pad structures.

According to an example embodiment, the forming the plurality of metal pad structures may include forming the protective insulating layer having pad holes over the substrate. A metal layer filling the pad holes and covering the protective insulating layer may be formed. A sacrificial layer may be formed over the metal layer. The metal layer and the sacrificial layer may be patterned to form the plurality of metal pad structures and a plurality of sacrificial patterns, the plurality of metal pad structures filling the pad holes and the plurality of sacrificial patterns covering the plurality of metal pad structures.

According to an example embodiment, the forming the insulating barrier spacers may include forming the insulating barrier spacers on the sidewalls of the plurality of metal pad structures and sidewalls of the plurality of sacrificial patterns. The plurality of sacrificial patterns may be removed to expose the top surfaces of the plurality of metal pad structures.

According to an example embodiment, the metal layer may be at least one of aluminum (Al) and an aluminum (Al) alloy.

According to an example embodiment, the insulating barrier spacers may include a material having an etch selectivity with respect to the sacrificial layer.

According to an example embodiment, the method may include before forming the protective insulating layer, forming an interlayer insulating layer on the substrate. Metal patterns passing through the interlayer insulating layer may be formed, and the metal patterns may be exposed by the pad holes.

According to an example embodiment, the metal patterns may include copper (Cu) interconnections.

According to an example embodiment, the method may include before forming the metal layer, forming a barrier layer on the substrate having the protective insulating layer, and the barrier layer may be patterned with the metal layer and the sacrificial layer to form a barrier pattern.

According to an example embodiment, the method may include forming an insulating buffer pattern outside the insulating barrier spacers.

According to an example embodiment, forming the insulating barrier spacers and forming the insulating buffer pattern may include forming the protective insulating layer having pad holes over the substrate. A metal layer filling the pad holes and covering the protective insulating layer may be formed. A sacrificial layer may be formed over the metal layer. The metal layer and the sacrificial layer may be patterned to form the plurality of metal pad structures and a plurality of sacrificial patterns, the plurality of metal pad structures filling the pad holes and the plurality of sacrificial patterns covering the plurality of metal pad structures. A spacer insulating layer and a buffer insulating layer may be formed on the substrate having the metal pad structures and the sacrificial patterns. The buffer insulating layer and the spacer insulating layer may be etched until top surfaces of the plurality of sacrificial patterns are exposed.

According to an example embodiment, the method may include forming bonding wires on the plurality of metal pad structures.

### BRIEF DESCRIPTION OF THE DRAWINGS

The above and/or other aspects and advantages will become more apparent and more readily appreciated from the following detailed description of example embodiments taken in conjunction with the accompanying drawings of which:

FIG. 1 is a plan view of an electronic device according to an example embodiment.

FIGS. 2A to 2E are cross-sectional views illustrating a method of fabricating an electronic device according to an example embodiment.

FIGS. 3A and 3B are cross-sectional views illustrating a method of fabricating an electronic device according to another example embodiment.

### DETAILED DESCRIPTION OF EXAMPLE EMBODIMENTS

Example embodiments will now be described more fully hereinafter with reference to the accompanying drawings. Embodiments may, however, be in many different forms and should not be construed as being limited to the example embodiments set forth herein. Rather, these example embodiments are provided so that this disclosure will be thorough and complete, and will fully convey the scope to those skilled in the art. In the drawings, the thicknesses of layers and regions may be exaggerated for clarity.

It will be understood that when a component is referred to as being “on,” “connected to” or “coupled to” another component, it can be directly on, connect to or coupled to the other component or intervening components may be present. In contrast, when a component is referred to as being “directly on,” “directly connected to” or “directly coupled to” another component, there are no intervening components present. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the example embodiments.

Spatially relative terms, such as “beneath,” “below,” “lower,” “above,” “upper” and the like, may be used herein for ease of description to describe one component or feature's relationship to another component(s) or feature(s) as illustrated in the drawings. It will be understood that the spatially relative terms are intended to encompass different orientations of the device in use or operation in addition to the orientation depicted in the figures.

The terminology used herein is for the purpose of describing particular example embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements and/or components, but do not preclude the presence or addition of one or more other features, integers, steps, operations, elements, and/or components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Reference will now be made to example embodiments, which are illustrated in the accompanying drawings, wherein like reference numerals refer to the like components throughout.

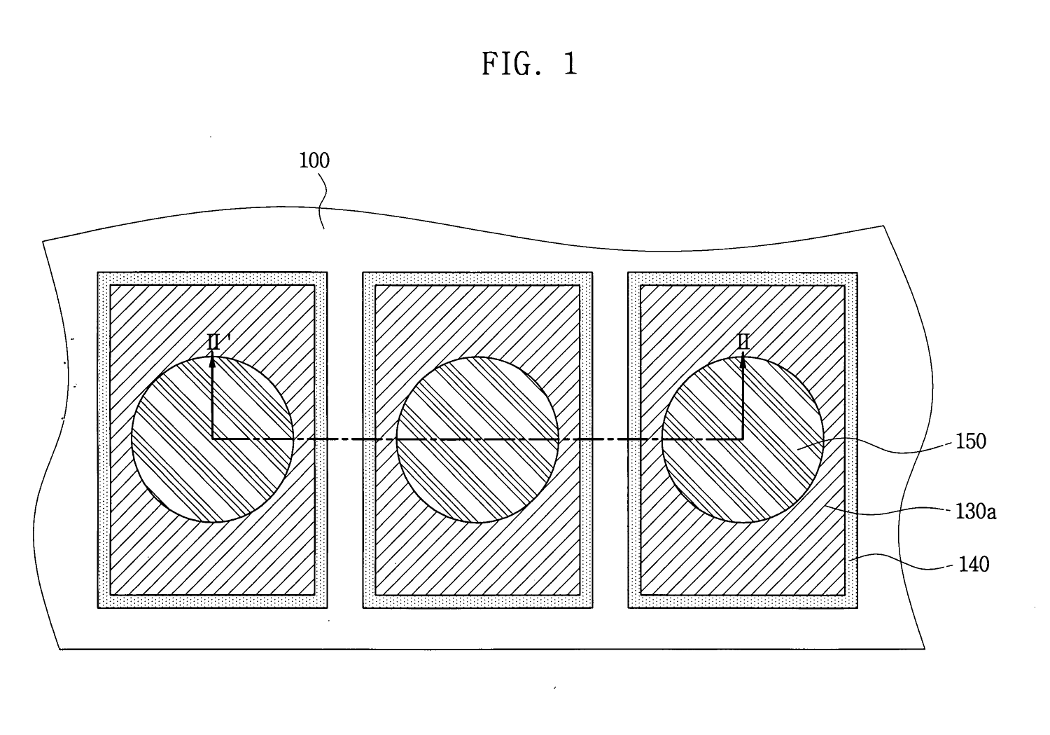

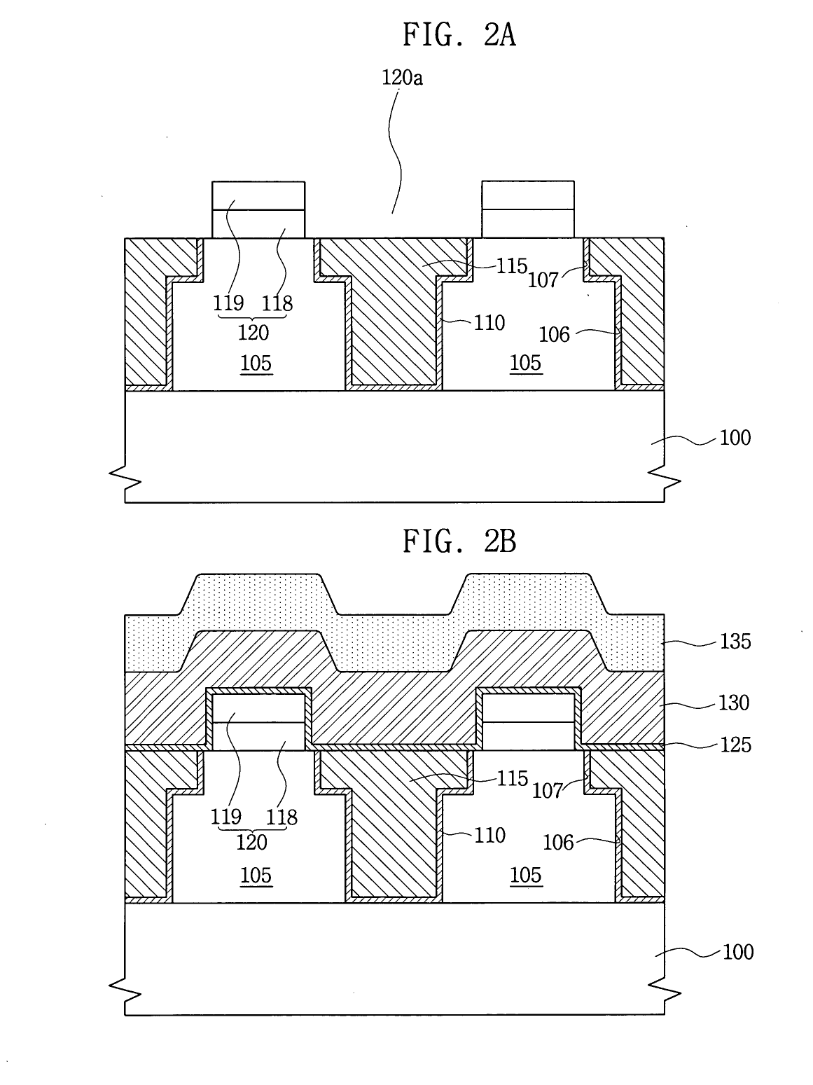

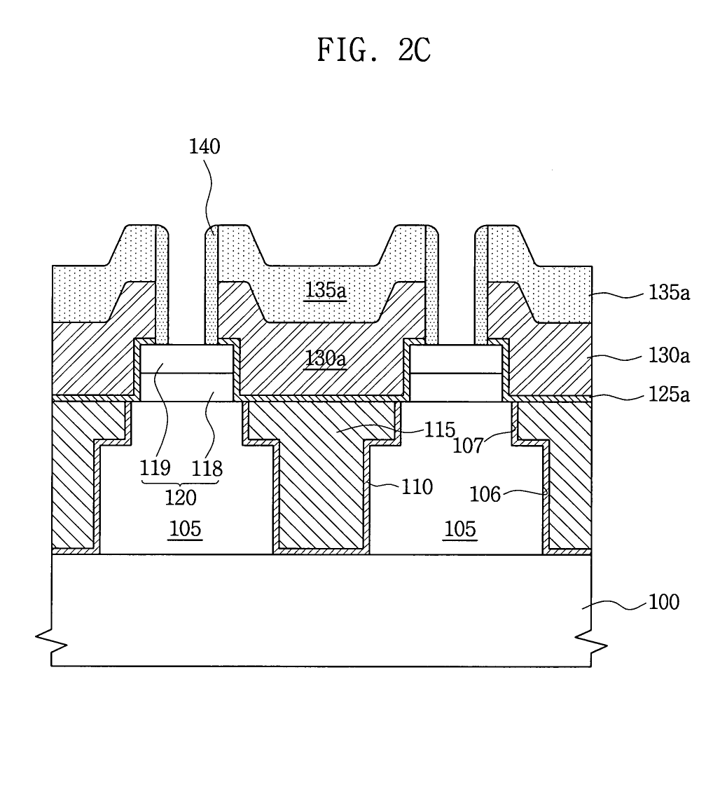

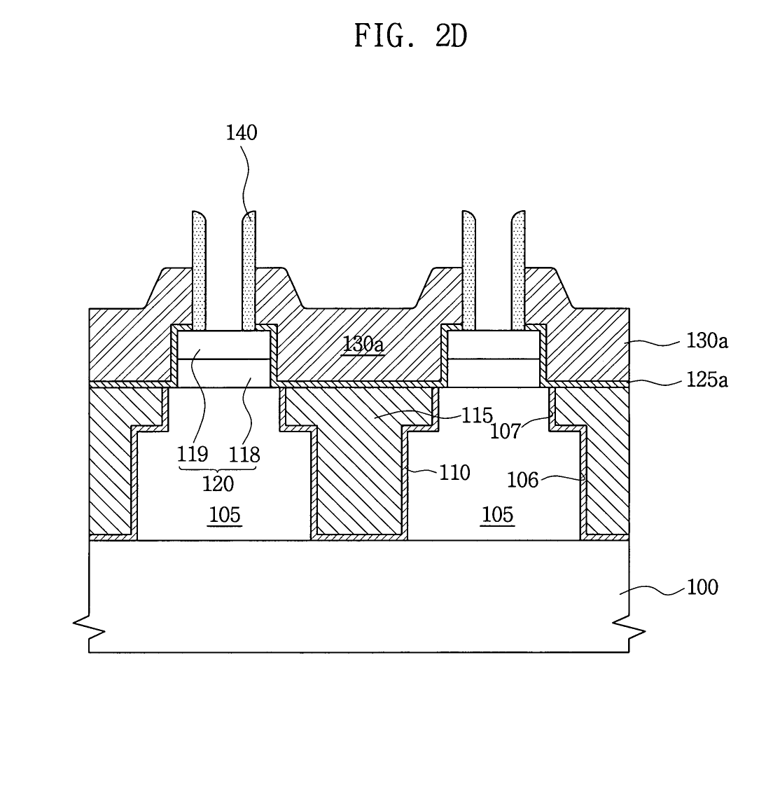

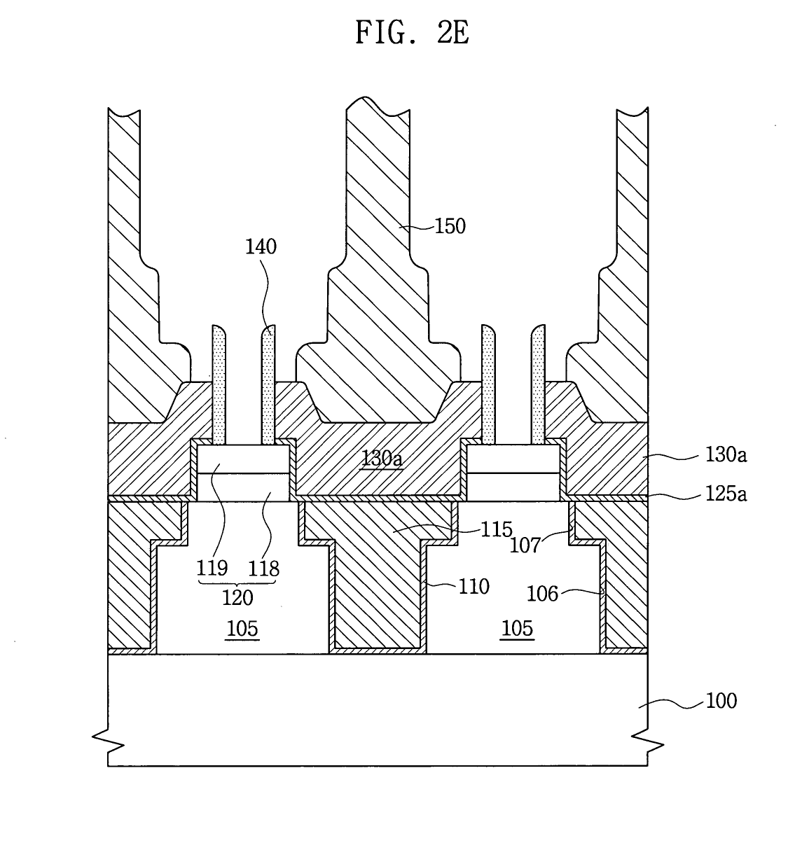

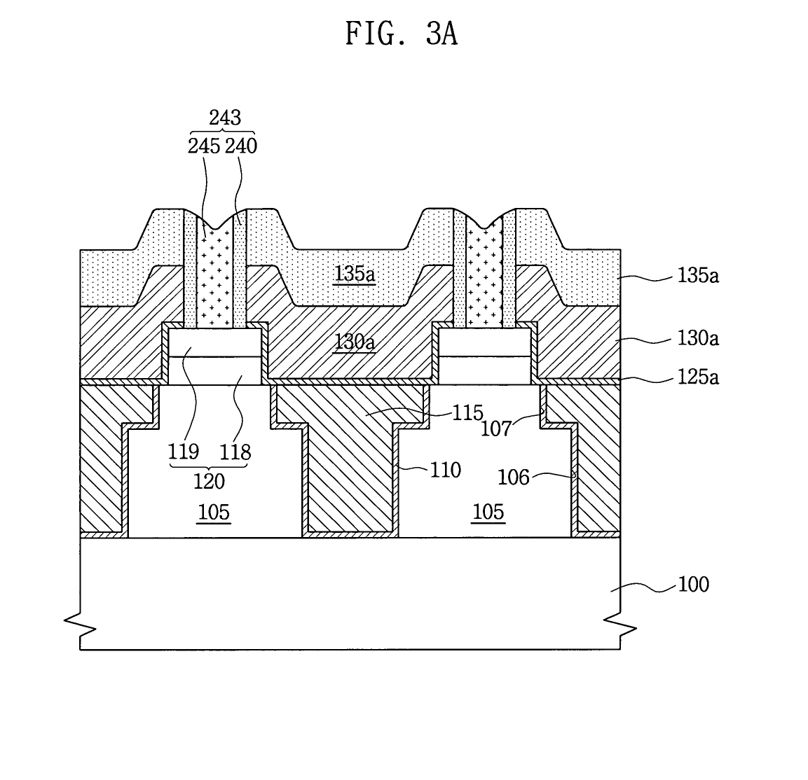

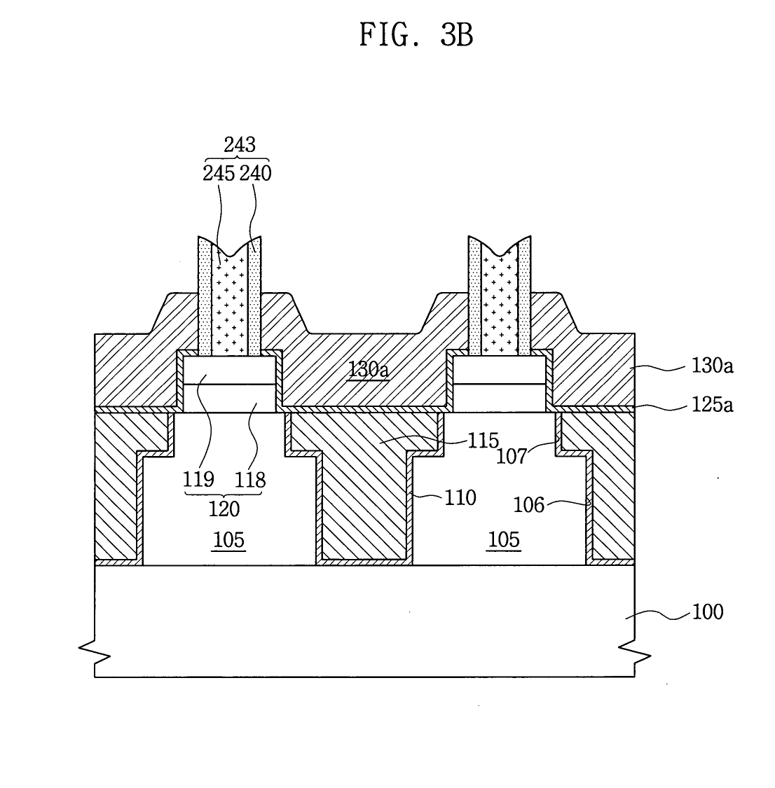

FIG. 1 is a plan view of an electronic device according to an example embodiment, FIGS. 2A to 2E are cross-sectional views taken along line II-II′ of FIG. 1, which illustrate a method of fabricating an electronic device according to an example embodiment, and FIGS. 3A and 3B are cross-sectional views illustrating a method of fabricating an electronic device according to another example embodiment.

A structure of an electronic device according to an example embodiment will be described with reference to FIGS. 1 and 2E.

Referring to FIGS. 1 and 2E, a substrate 100 may be prepared. The substrate 100 may be a semiconductor substrate having a conductive region. An interlayer insulating layer 105 may be on the substrate 100. The interlayer insulating layer 105 may be a silicon oxide layer. Alternatively, the interlayer insulating layer 105 may be formed of a low-k dielectric layer with a lower dielectric constant than a silicon oxide layer to improve an operating speed of a semiconductor device. For example, the low-k dielectric layer may be a fluorine-doped silicate glass (FSG) layer, a hydrogen silsesquioxane (HSQ) layer, or a methyl silsesquioxane (MSQ or SiOC) layer.

Metal patterns 115 may pass through the interlayer insulating layer 105 and/or contact a desired, or alternatively, a predetermined region of the substrate 100. The metal patterns 115 may be damascene interconnect structures. For example, the metal patterns 115 may be copper (Cu) interconnections having a damascene interconnect structure.

Lower barrier patterns 110 may be interposed between the metal patterns 115 and the interlayer insulating layer 105. The lower barrier patterns 110 may include a metal nitride layer, for example, a titanium nitride layer or a tantalum nitride layer. If the metal patterns 115 are formed of a Cu layer, the lower barrier patterns 110 may reduce diffusion of Cu elements in the metal patterns 115 into the substrate 100.

A protective insulating layer 120 may be on the substrate having the metal patterns 115. The protective insulating layer 120 may include a lower insulating layer 118 and/or an upper insulating layer 119. The lower insulating layer 118 and the upper insulating layer 119 may be sequentially stacked. The lower insulating layer 118 may include a silicon oxide layer, and/or the upper insulating layer 119 may include a silicon nitride layer. The upper insulating layer 119 may reduce penetration of moisture or contaminant into the substrate 100 from the outside.

Metal pad structures 130a may pass through the protective insulating layer 120 and/or have a top surface disposed at a higher level than the protective insulating layer 120. For example, the metal pad structures 130a may be plural and spaced apart from one another. The top surfaces of the metal pad structures 130a may be completely exposed. The metal pad structures 130a may have a first width at a part passing through the protective insulating layer 120, and a second width larger than the first width at a part that is disposed at a higher level than the protective insulating layer 120. Accordingly, the metal pad structures 130a may pass through the protective insulating layer 120 and/or partially cover the top surface of the protective insulating layer 120. The metal pad structures 130a may be formed of an aluminum (Al) layer or an Al alloy layer, e.g., the Al alloy layer may include an aluminum (Al) element and a copper (Cu) element.

Upper barrier patterns 125a may be interposed between the metal pad structures 130a and the metal patterns 115. The upper barrier patterns 125a may include a metal nitride layer, for example, a titanium nitride layer or a tantalum nitride layer.

Insulating barrier spacers 140 may be on sidewalls of the metal pad structures 130a. The insulating barrier spacers 140 may have top surfaces disposed at a higher level than the metal pad structures 130a. The insulating barrier spacers 140 may be disposed at a higher level than the protective insulating layer 120. For example, the insulating barrier spacers 140 may surround the metal pad structures 130a disposed at a higher level than the protective insulating layer 120, and/or have top surfaces higher than the metal pad structures 130a. The insulating barrier spacers 140 may be formed of a silicon nitride layer.

Although not illustrated in the figures, the substrate having the insulating barrier spacers 140 may be connected to a package base, for example, a lead frame. The substrate 100 and the package base may be electrically connected to each other by bonding wires 150. The bonding wires 150 may be formed of gold wire. For example, the bonding wires 150 may be formed on the metal pad structures 130a at one end, and on the package base at the other end. For example, an end portion of the bonding wire 150 in contact with the metal pad structure 130a may be wider than another portion of the bonding wire 150. Because the top surfaces of the metal pad structures 130a are completely exposed, and the insulating barrier spacers 140 surrounding the metal pad structures 130a are provided, the contact area between the metal pad structures 130a and the bonding wires 150 may increase, and/or an occurrence of an electrical short circuit between the bonding wires 150 may be reduced. Due to the increased contact area between the metal pad structures 130a and the bonding wires 150, electrical characteristics between the metal pad structures 130a and the bonding wires 150 may be improved. As illustrated in FIG. 2E, the insulating barrier spacers 140 may be disposed between the ends of the bonding wires 150 that are in contact with the metal pad structures 130a, so that an occurrence of an electrical short circuit between the ends of the bonding wires 150 may be reduced.

According to another example embodiment, as illustrated in FIG. 3B, barrier patterns 243 may fill spaces between the metal pad structures 130a. The barrier patterns 243 fill spaces between the metal pad structures 130a, which may be mechanically stabilized, in order to reduce an occurrence of an electrical short circuit between the ends of the bonding wires 150. For example, the barrier patterns 243 may surround the metal pad patterns 130a disposed at a higher level than the protective insulating layer 120, and/or have a top surface disposed at a higher level than the metal pad structures 130a. The barrier patterns 243 may include insulating barrier spacers 240 surrounding the metal pad patterns 130a and/or having top surfaces disposed at a higher level than the metal pad structures 130a, and/or an insulating buffer pattern 245 disposed outside the insulating barrier spacers 240.

Methods of fabricating an electronic device according to example embodiments will be described below.

A method of fabricating an electronic device according to an example embodiment will be described with reference to FIGS. 2A to 2E.

Referring to FIG. 2A, a substrate 100 may be prepared. The substrate 100 may be a semiconductor substrate including a conductive region. The substrate 100 may include a lower metal interconnection of at least one layer. An interlayer insulating layer 105 may be formed on the substrate 100. The interlayer insulating layer 105 may be a silicon oxide layer.

Alternatively, the interlayer insulating layer 105 may be a low-k dielectric layer having a lower dielectric constant than a silicon oxide layer to improve an operating speed of a semiconductor device. For example, the low-k dielectric layer may be a FSG layer, HSQ layer, or a MSQ or SiOC layer.

Metal patterns 115 passing through the interlayer insulating layer 105 and electrically connected to a desired, or alternatively, a predetermined region of the substrate 100 may be formed. The metal patterns 115 may be formed of a Cu interconnection. For example, via holes 106 and/or trenches 107 may be formed in the interlayer insulating layer 105 by a damascene technique. In other words, the via holes 106 passing through the interlayer insulating layer 105 to expose a desired, or alternatively, a predetermined region of the substrate 100 may be formed, and the trenches 107 crossing over the via hole 106 may be formed in the interlayer insulating layer 105. A lower barrier layer and a metal layer may be sequentially stacked on the substrate having the via holes 106 and the trenches 107. The lower barrier layer may include a metal nitride layer, for example, a tantalum nitride layer or a titanium nitride layer. The metal layer may be formed of Cu. The metal layer and the lower barrier layer may be planarized until the interlayer insulating layer 105 is exposed. Accordingly, lower barrier patterns 110 may be formed on inner walls of the via holes 106 and trenches 107, and/or metal patterns 115 filling the via holes 106 and the trenches 107 may be formed on the lower barrier patterns 110. The lower barrier patterns 110 may reduce penetration of metal elements of the metal patterns 115, for example, Cu elements, into the substrate 100.

A protective insulating layer 120 having pad holes 120a that expose the metal patterns 115 may be formed on the substrate having the metal patterns 115. The protective insulating layer 120 may be formed of a lower insulating layer 118 and an upper insulating layer 119, which may be sequentially stacked. The lower insulating layer 118 may be a silicon oxide layer. The upper insulating layer 119 may be a silicon nitride layer. The upper insulating layer 119 may reduce penetration of moisture and/or contaminants into the substrate 100 from the outside.

Referring to FIG. 2B, a conductive upper barrier layer 125 may be formed on the substrate having the protective insulating layer 120. The upper barrier layer 125 may be a conductive metal nitride layer, for example, a tantalum nitride layer or a titanium nitride layer. A metal layer 130, a buffer layer (not illustrated) and a sacrificial layer 135 may be stacked, e.g., sequentially stacked, on the upper barrier layer 125. The buffer layer may be formed of a material having an etch selectivity with respect to the sacrificial layer 135 and/or the metal layer 130. However, the buffer layer may be omitted. The metal layer 130 may be formed of Al or an alloy thereof, e.g., the Al alloy layer may include an aluminum (Al) element and a copper (Cu) element. The sacrificial layer 135 may be formed of a material having an etch selectivity with respect to the upper insulating layer 119. For example, if the upper insulating layer 119 is a silicon nitride layer, the sacrificial layer 135 may be a silicon oxide layer.

Referring to FIG. 2C, upper barrier patterns 125a, metal pad structures 130a, and/or sacrificial patterns 135a may be formed by patterning the sacrificial layer 135, the metal layer 130, and/or the upper barrier layer 125. The upper barrier patterns 125a, the metal pad structures 130a, and the sacrificial patterns 135a may be sequentially stacked. The metal pad structure 130a may be formed to fill the pad holes 120aand/or have a higher top surface than the protective insulating layer 120. The metal pad structures 130a may be spaced apart from each other. The metal pad structures 130a may at least partially cover the top surface of the protective insulating layer 120 disposed between the metal pad structures 130a.

A spacer insulating layer may be formed on the substrate having the upper barrier patterns 125a, the metal pad structures 130a and the sacrificial patterns 135a, which are sequentially stacked. The spacer insulating layer may be anisotropically etched to form insulating barrier spacers 140. The insulating barrier spacers 140 may be formed on sidewalls of the upper barrier patterns 125a, sidewalls of the pad structures 130a and/or sidewalls of the sacrificial patterns 135a. The spacer insulating layer may be formed of a material having an etch selectivity with respect to the sacrificial patterns 135a. For example, if the sacrificial patterns 135a are formed of a silicon oxide layer, the insulating barrier spacers 140 may be formed of a silicon nitride layer.

Referring to FIG. 2D, the sacrificial patterns 135a (e.g., as illustrated in FIG. 2C) may be selectively removed to expose the top surfaces of the metal pad structures 130a. For example, the top surfaces of the metal pad structures 130a may be completely exposed. The insulating barrier spacers 140 may be formed of a material having an etch selectivity with respect to the sacrificial patterns 135a, so that the insulating barrier spacers 140 remain during the removal of the sacrificial patterns 135a. Accordingly, the insulating barrier spacers 140 may have top surfaces disposed at a higher level than the metal pad structures 130a.

Referring to FIG. 2E, the substrate having the insulating barrier spacers 140 may be connected to a package base, for example, a lead frame package substrate (not illustrated). Bonding wires 150 electrically connecting the substrate having the insulating barrier spacers 140 to the package base may be provided. The bonding wires 150 may be gold wires. An end of the bonding wire 150 may be formed on the metal pad structure 130a by a bonding technique, for example, a thermo-compression bonding technique. Accordingly, the end of the bonding wire 150 in contact with the metal pad structure 130a may have a wider width. The insulating barrier spacers 140 may surround the metal pad structures 130a, and/or have top surfaces disposed at a higher level than the metal pad structures 130a. Accordingly, the insulating barrier spacers 140 may reduce an occurrence of an electrical short circuit between the bonding wires 150.

An electronic device according to another example embodiment will be described with reference to FIGS. 3A and 3B.

Referring to FIG. 3A, the substrate 100 having the sacrificial layer 135, which is illustrated in FIGS. 2A and 2B, may be prepared. As illustrated in FIG. 2C, the upper barrier patterns 125a, the metal pad structures 130a, and/or the sacrificial patterns 135a, which may be sequentially stacked, may be formed by sequentially patterning the sacrificial layer 135, the metal layer 130, and the upper barrier layer 125.

Barrier patterns 243, which may fill spaces between the metal pad structures 130a and/or between the sacrificial patterns 135a, may be formed. The barrier patterns 243 may be formed of a material having an etch selectivity with respect to the sacrificial patterns 135a. For example, a spacer insulating layer may be formed on the substrate having the upper barrier patterns 125a, the metal pad structures 130a, and the sacrificial patterns 135a. An insulating buffer layer filling spaces between the metal pad structures 130a and/or between the sacrificial patterns 135a may be formed on the spacer insulating layer. Insulating barrier spacers 240 and/or insulating buffer patterns 245 remaining between the metal pad structures 130a and/or between the sacrificial patterns 135a may be formed by etching the insulating buffer layer and/or the spacer insulating layer until top surfaces of the sacrificial patterns 135a are exposed. The insulating barrier spacers 240 may be formed on sidewalls of the metal pad structures 130a, sidewalls of the sacrificial patterns 135a, and/or on the protective insulating layer 120 between the metal pad structures 130a. Accordingly, the barrier patterns 243 formed of the insulating barrier spacers 240 and the insulating buffer patterns 245 may be formed. The barrier patterns 243 may surround the metal patterns 130a disposed at a higher level than the protective insulating layer 120, and/or have top surfaces disposed at a higher level than the metal pad structures 130a.

Referring to FIG. 3B, the sacrificial patterns 135a (e.g., as illustrated in FIG. 2C) may be selectively removed by a similar method as illustrated in FIG. 2D, thereby exposing top surfaces of the metal pad structures 130a. For example, the top surfaces of the metal pad structures 130a may be completely exposed. The barrier patterns 243 may be formed of a material having an etch selectivity with respect to the sacrificial pattern 135a, so that the insulating barrier spacers 140 may remain during the removal of the sacrificial patterns 135a. Accordingly, the insulating barrier spacers 140 may have top surfaces disposed at a higher level than the metal pad structures 130a. Although not illustrated in FIG. 3B, bonding wires may be provided on the metal pad structures 130a using a similar method as illustrated in FIG. 2E.

According to example embodiments, insulating barrier spacers surrounding sidewalls of metal pad structures having finer pitches and/or having a top surface disposed at a higher level than the metal pad structures may be provided. Because the insulating barrier spacers are disposed between the metal pad structures and/or have a top surface disposed at a higher level than the metal pad structures, an occurrence of an electrical short circuit between bonding wires formed on the metal pad structures may be reduced.

Although example embodiments have been shown and described in this specification and figures, it would be appreciated by those skilled in the art that changes may be made to the illustrated and/or described example embodiments without departing from their principles and spirit.

What is claimed is:

1. An electronic device, comprising:
a substrate
a protective insulating layer formed over the substrate;
a plurality of metal pad structures spaced apart from one another, each of the plurality of metal pad structures passing through the protective insulating layer and including a top surface disposed at a higher level than the protective insulating layer; and
insulating barrier spacers on sidewalls of the plurality of metal pad structures, each of the insulating barrier spacers including a top surface disposed at a higher level than the metal pad structures.

2. The electronic device according to claim 1, wherein the plurality of metal pad structures have a first width at a first part passing through the protective insulating layer and a second width larger than the first width at a second part disposed at a higher level than the protective insulating layer.

3. The electronic device according to claim 2, wherein the plurality of metal pad structures partially cover a top surface of the protective insulating layer.

4. The electronic device according to claim 1, wherein the plurality of metal pad structures are at least one of an aluminum (Al) layer and an aluminum (Al) alloy layer.

5. The electronic device according to claim 1, wherein the insulating barrier spacers are disposed at a higher level than the protective insulating layer.

6. The electronic device according to claim 1, wherein the insulating barrier spacers cover sidewalls of the metal pad structures and a top surface of the protective insulating layer between the metal pad structures.

7. The electronic device according to claim 1, wherein the insulating barrier spacers include a silicon nitride layer.

8. The electronic device according to claim 1, further comprising:
an insulating buffer pattern formed outside the insulating barrier spacers and filling a space between each of the plurality of metal pad structures.

9. The electronic device according to claim 1, further comprising:
an interlayer insulating layer formed between the substrate and the protective insulating layer; and
metal patterns passing through the interlayer insulating layer and electrically connected to the plurality of metal pad structures.

10. The electronic device according to claim 9, wherein the metal patterns include copper (Cu) interconnections.

11. The electronic device according to claim 9, further comprising:
barrier patterns interposed between the metal patterns and the plurality of metal pad structures.

12. The electronic device according to claim 1, further comprising:
bonding wires on the plurality of metal pad structures.

13. The electronic device according to claim 12, wherein a portion of each of the bonding wires contacting the plurality of metal pad structures is wider than another portion of each of the bonding wires.

14. A method of fabricating an electronic device, comprising:
forming a plurality of metal pad structures spaced apart from one another and passing through a protective insulating layer formed over a substrate, each of the plurality of metal pad structures including a top surface disposed at a higher level than the protective insulating layer; and
forming insulating barrier spacers on sidewalls of the plurality of metal pad structures, each of the insulating barrier spacers including a top surface disposed at a higher level than the metal pad structures.

15. The method according to claim 14, wherein the forming the plurality of metal pad structures includes,
forming the protective insulating layer having pad holes over the substrate;
forming a metal layer filling the pad holes and covering the protective insulating layer;
forming a sacrificial layer over the metal layer;
patterning the metal layer and the sacrificial layer to form the plurality of metal pad structures and a plurality of sacrificial patterns, the plurality of metal pad structures filling the pad holes and the plurality of sacrificial patterns covering the plurality of metal pad structures.

16. The method according to claim 15, wherein the forming the insulating barrier spacers includes,
forming the insulating barrier spacers on the sidewalls of the plurality of metal pad structures and sidewalls of the plurality of sacrificial patterns; and
removing the plurality of sacrificial patterns to expose the top surfaces of the plurality of metal pad structures.

17. The method according to claim 15, wherein the metal layer is at least one of aluminum (Al) and an aluminum (Al) alloy.

18. The method according to claim 15, wherein the insulating barrier spacers include a material having an etch selectivity with respect to the sacrificial layer.

19. The method according to claim 15, before forming the protective insulating layer, further comprising:
forming an interlayer insulating layer on the substrate; and
forming metal patterns passing through the interlayer insulating layer, wherein the metal patterns are exposed by the pad holes.

20. The method according to claim 19, wherein the metal patterns include copper (Cu) interconnections.

21. The method according to claim 15, before forming the metal layer, further comprising:
forming a barrier layer on the substrate having the protective insulating layer, wherein the barrier layer is patterned with the metal layer and the sacrificial layer to form a barrier pattern.

22. The method according to claim 14, further comprising:
forming an insulating buffer pattern outside the insulating barrier spacers.

23. The method according to claim 22, wherein forming the insulating barrier spacers and forming the insulating buffer pattern includes,
forming the protective insulating layer having pad holes over the substrate;
forming a metal layer filling the pad holes and covering the protective insulating layer;
forming a sacrificial layer over the metal layer;
patterning the metal layer and the sacrificial layer to form the plurality of metal pad structures and a plurality of sacrificial patterns, the plurality of metal pad structures filling the pad holes and the plurality of sacrificial patterns covering the plurality of metal pad structures;
forming a spacer insulating layer and a buffer insulating layer on the substrate having the metal pad structures and the sacrificial patterns; and
etching the buffer insulating layer and the spacer insulating layer until top surfaces of the plurality of sacrificial patterns are exposed.

24. The method according to claim 14, further comprising:
forming bonding wires on the plurality of metal pad structures.
